(19) United States
(12) Patent Application Publication
(10) Pub. No.: US 2021/0384346 A1
(43) Pub. Date: Dec. 9, 2021

(54) SHIELDED GATE TRENCH MOSFET HAVING SUPER JUNCTION SURROUNDING LOWER PORTION OF TRENCHED GATES

(71) Applicant: Nami MOS CO., LTD., New Taipei City (TW)

(72) Inventor: Fu-Yuan HSIEH, New Taipei City (TW)

(73) Assignee: Nami MOS CO., LTD., New Taipei City (TW)

(21) Appl. No.: 16/891,105

(22) Filed: Jun. 3, 2020

(51) Int. Cl. H01L 29/78; H01L 29/06; H01L 29/40; H01L 29/66

(52) U.S. Cl. CPC H01L 29/7813; H01L 29/66734; H01L 29/407; H01L 29/0634

(57) ABSTRACT

An SGT MOSFET having super junction surrounding lower portion of trenched gates is disclosed. The super junction structure is surrounding lower portion of trenched gates to ensure whole drift region is fully depleted and breakdown occurs at middle of adjacent trenched gates without having early breakdown occurring at trench bottom. Moreover, sensitivity of breakdown voltage on trench bottom oxide thickness and trench depth is significantly relaxed or immune. Avalanche capability is also enhanced.

### FIELD OF THE INVENTION

This invention relates generally to semiconductor devices, and more particularly, to a shielded gate trench MOSFET (Metal Oxide Semiconductor Field Effect Transistor) having a super junction structure surrounding lower portion of trenched gates to avoid early breakdown occurring at trench bottom, achieve lower on-resistance and enhance avalanche capability.

### BACKGROUND OF THE INVENTION

FIG. 1A and FIG. 1B show two types of shielded gate trench MOSFETs (SGT) which have much lower gate charge and on-resistance compared with traditional single gate trench MOSFETs as results of existence of oxide charge balance region in drift region and thick oxide underneath gate electrode. However, an early breakdown always occurs at trench bottom and a degradation of the breakdown voltage (BV) is therefore becoming a design and operation limitation.

Another disadvantage of SGT MOSFET is cell pitch becoming larger than 2.5 μm when BV is higher than 100V because of thick shielded gate oxide requirement for oxide charge balance. This results in limitation of specific on-resistance reduction.

Therefore, there is still a need in the art of the semiconductor device design and fabrication, particularly for SGT MOSFET design and fabrication, to provide a novel cell structure, device configuration and manufacturing process that making an SGT MOSFET have stable breakdown voltage, achieve lower on-resistance and enhance avalanche capability.

### SUMMARY OF THE INVENTION

The present invention provides an SGT MOSFET having a super junction structure surrounding lower portion of trenched gates to ensure whole drift region is fully depleted and breakdown occurs at middle of adjacent trenched gates without having early breakdown occurring at trench bottom. Moreover, sensitivity of breakdown voltage on trench bottom oxide thickness and trench depth is significantly relaxed or immune. Avalanche capability is also enhanced.

According to one aspect, the invention features a trenched semiconductor power device comprising an SGT MOSFET formed in an epitaxial layer of a first conductivity type onto a substrate of the first conductivity type, further comprising: a plurality of trenched gates surrounded by source regions of the first conductivity type encompassed in body regions of a second conductivity type near a top surface of the epitaxial layer, wherein each of the trenched gates includes a gate electrode and a shielded gate electrode; an oxide charge balance region formed between upper portion of adjacent trenched gates; a super junction region surrounding with lower portion of the trenched gates, comprising a first doped column region of the second conductivity type formed adjacent to sidewalls of the trenched gates and a second doped column region of the first conductivity type formed in parallel and surrounded with the first doped column regions below the oxide charge balance region; the shielded gate electrode being insulated from the epitaxial layer by a first insulating film and the gate electrode being insulated from the epitaxial layer by a second insulting film having a less thickness than the first insulating film, the first insulating film, the shielded gate electrode and the gate electrode being insulated from each other; and the body regions, the shielded gate electrodes and the source regions being shorted to a source metal through a plurality of trenched contacts. Each of trenched gates has first type gate trench and second type gate trench. The second type gate trench is below the first type gate trench and has trench width narrower than the first type gate trench. The gate electrode is disposed in the first type gate trench, and the shielded gate is in the first and second type gate trenches or only in the first type gate trench. The super junction region surrounds with the second type gate trench which is in lower portion of the trenched gates.

According to another aspect, in some preferred embodiments, the epitaxial layer comprises a single epitaxial layer having uniform doping concentration. In some other preferred embodiments, the epitaxial layer comprises a lower epitaxial layer between the substrate and the gate trench with resistivity R1 and an upper epitaxial layer with resistivity R2, wherein R1<R2. In some other preferred embodiments, the epitaxial layer comprises a lower epitaxial layer between the substrate and bottom of trenched gates with resistivity R1, a middle epitaxial layer located in the super junction region with resistivity R2 and an upper epitaxial layer with resistivity R3, wherein R1<R2<R3 or R1<R3<R2.

According to another aspect, in some preferred embodiments, the super junction region surrounding with at least lower portion of shielded gate electrode. In some other preferred embodiments, lower portion of the trenched gates has a narrow trench fully filled up with the first insulating film and is surrounded by the super junction region.

In some other preferred embodiments, the shielded gate electrode is disposed in the middle and the gate electrode is a pair of split gate electrodes disposed surrounding upper portion of the shielded gate electrode, the gate electrode and the shielded gate electrode are insulated from each other by the second insulating film grown on upper portion of the shielded gate electrode. In some other preferred embodiments, the upper portion of the shielded gate electrode surrounded by the gate electrode is fully oxidized as a third insulating film during the second insulating film grown when the shielded gate electrode is thin enough. The pair of split gate electrodes are separated from each other by the third insulating film.

According to another aspect, in some preferred embodiment, the shielded gate electrode is disposed in lower portion of each trenched gate, and is isolated from the epitaxial layer by the first insulating film, the gate electrode is disposed in upper portion of each trenched gate, and is isolated from the shielded gate electrode by a fourth insulating film.

The present invention also features a method for manufacturing a trench semiconductor power device comprising the steps of: (a) growing an epitaxial layer of a first conductivity type onto a substrate of the first conductivity type, wherein the epitaxial layer having a lower doping concentration than the substrate; (b) forming a trench mask onto a top surface of the epitaxial layer for definition of a plurality of first type gate trenches; (c) forming the first type gate trenches, and a mesa between two adjacent gate trenches in the epitaxial layer by etching through open regions in the trench mask; (d) forming a dielectric layer on sidewalls and bottoms of the first type gate trenches; (e) removing the dielectric layer from the bottoms of the first type gate trenches by anisotropic etch; (f) performing an anisotropic silicon etch to form a plurality of second type gate trenches; (g) carrying out an angle Ion Implantation of the second conductivity type dopant into the sidewalls of the second type gate trenches.

According to another aspect, in some preferred embodiment, the method for manufacturing a trench semiconductor power device further comprising the steps of: (h) forming a first insulating film along inner surfaces of the first type and the second type gate trenches; (i) depositing a first doped poly-silicon layer filling the first type and second type gate trenches to serve as a shielded gate electrode in the first type and second type gate trenches; (j) etching back the first insulation layer of upper portion of the first gate trench sidewalls for formation of a pair of gate electrodes surrounding the shielded gate electrode; (k) forming a second insulating film as a gate oxide layer along upper sidewalls of the first type gate trenches; (l) depositing a second doped poly-silicon layer to serve as the pair of gate electrodes.

According to another aspect, in some preferred embodiment, the method for manufacturing a trench semiconductor power device further comprising the steps of: (h′) forming a first insulation film along inner surfaces of the first type and the second type gate trenches, wherein the second type gate trenches is fully filled up by the first insulation film; (i) depositing a first doped poly-silicon layer filling the first type gate trenches to serve as a shielded gate electrode in the first type gate trenches; (j′) etching back the first insulating film of upper sidewalls of the first type gate trenches for formation of a pair of gate electrodes surrounding the shielded gate electrode; (k′) forming a second insulating film as a gate oxide layer along upper sidewalls of the first type gate trenches; (l′) depositing a second doped poly-silicon layer to serve as the pair of gate electrodes.

According to another aspect, in some preferred embodiment, the method for manufacturing a trench semiconductor power device further comprising the steps of: (h″) forming a first insulating film along inner surfaces of the first type and the second type gate trenches; (i″) depositing a first doped poly-silicon layer filling the first type and second type gate trenches to serve as a shielded gate electrode; (j″) etching back the first doped poly-silicon to form a shielded gate electrode in the second type gate trenches and lower portion of the first type gate trenches; (k″) etching back the first insulating film of upper portion of the first gate trench sidewalls for formation of a gate electrode; (l″) forming a second insulating film as a gate oxide layer along upper sidewalls of the first type gate trenches; (m″) depositing a second doped poly-silicon layer to serve as the gate electrode.

According to another aspect, in some preferred embodiment, the method for manufacturing a trench semiconductor power device further comprising the steps of: (h′″) forming a first insulating film along inner surfaces of the first type and the second type gate trenches, wherein the second type gate trenches is fully filled up by the first insulation film; (i′″) depositing a first doped poly-silicon layer filling the first type gate trenches to serve as a shielded gate electrode; (j′″) etching back the first doped poly-silicon to form the shielded gate electrode in lower portion of the first type gate trenches; (k′″) etching back the first insulating film of upper portion of the first gate trench sidewalls for formation of a gate electrode in upper portion of the first type gate trenches; (l′″) forming a second insulating film as a gate oxide layer along upper sidewalls of the first type gate trenches; (m′″) depositing a second doped poly-silicon layer to serve as the gate electrode.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1A is a cross-sectional view of an SGT MOSFET of prior art.

FIG. 1B is a cross-sectional view of another SGT MOSFET of prior art.

FIG. 2A is a cross-sectional view of a preferred embodiment according to the present invention.

FIG. 2B is a cross-sectional view of another preferred embodiment according to the present invention.

FIG. 2C is a cross-sectional view of another preferred embodiment according to the present invention.

FIG. 3A is a cross-sectional view of another preferred embodiment according to the present invention.

FIG. 3B is a cross-sectional view of another preferred embodiment according to the present invention.

FIG. 3C is a cross-sectional view of another preferred embodiment according to the present invention.

FIG. 4A is a cross-sectional view of another preferred embodiment according to the present invention.

FIG. 4B is a cross-sectional view of another preferred embodiment according to the present invention.

FIG. 4C is a cross-sectional view of another preferred embodiment according to the present invention.

FIG. 5A is a cross-sectional view of another preferred embodiment according to the present invention.

FIG. 5B is a cross-sectional view of another preferred embodiment according to the present invention.

FIG. 5C is a cross-sectional view of another preferred embodiment according to the present invention.

FIG. 6A is a cross-sectional view of another preferred embodiment according to the present invention.

FIG. 6B is a cross-sectional view of another preferred embodiment according to the present invention.

FIG. 6C is a cross-sectional view of another preferred embodiment according to the present invention.

FIGS. 7A-7G are a serial of side cross-sectional views for showing the processing steps for fabricating the trenched MOSFET of FIG. 2A, wherein the wide second type gate trench is filled up with both oxide and shielded gate electrode.

FIGS. 8A-8C are a serial of side cross-sectional views for showing the processing steps for fabricating the trenched MOSFET of FIG. 5A, wherein the narrow second type gate trench is fully filled up with oxide.

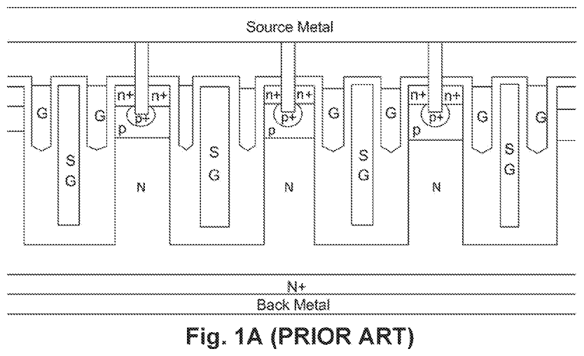

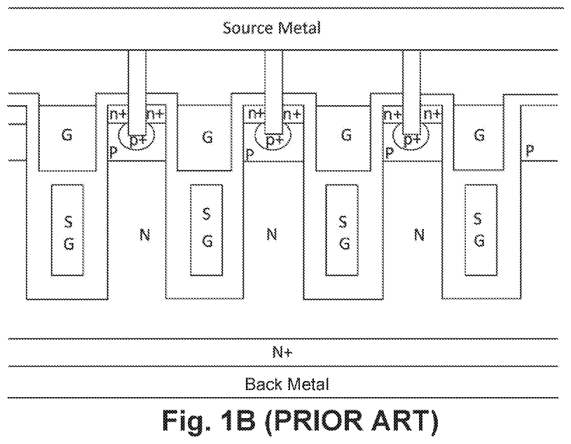

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

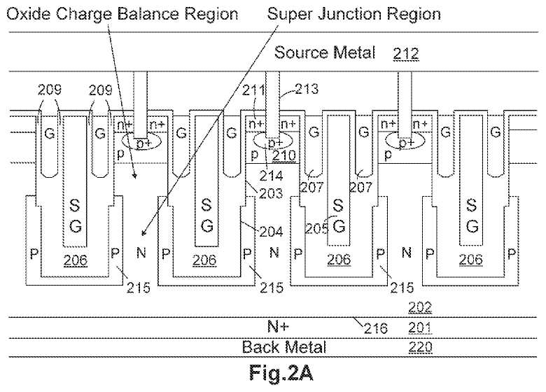

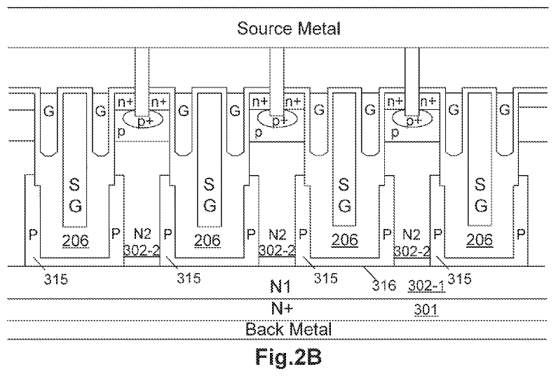

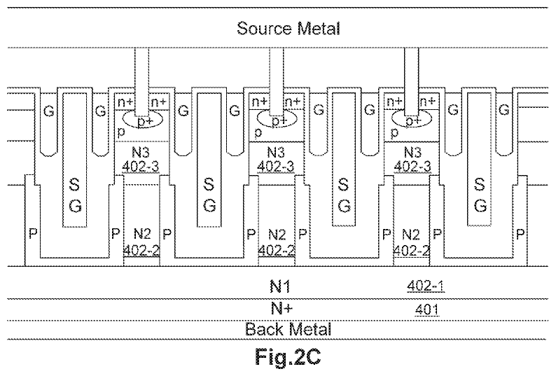

Please refer to FIG. 2A for a preferred embodiment of this invention. A trenched semiconductor power device comprises an N-channel SGT MOSFET formed on an N+ substrate 201 with a less doped single N epitaxial layer 202 extending thereon, wherein the N+ substrate 201 is coated with a back metal 220 of Ti/Ni/Ag on rear side as a drain metal. Inside the N epitaxial layer 202, a plurality of the trenched gates having first type gate trenches 203 and second type gate trenches 204 are formed vertically downward from the top surface of the epitaxial layer and not reaching the interface between the N epitaxial layer 202 and the N+ substrate 201, wherein the width of the second type gate trenches 204 is narrower than that of the first type gate trenches 203. In each of the first type gate trenches 203 and second type gate trenches 204, a shielded electrode 205 (SG as illustrated) is disposed in the middle of the trenches; the gate electrode is a pair of split gate electrodes 207, and is disposed surrounding upper portion of the first gate trench sidewalls and the shielded gate electrode 205. The shielded gate electrode 205 is insulated from the N epitaxial layer 202 by a first insulating film 206, and the gate electrode 207 is insulated from the N epitaxial layer 202 and the shielded gate electrode by a second insulating film 209 as a gate oxide layer having a less thickness than the first insulating film 206. Between every two adjacent trenched gates 203, a P body region 210 with n+ source regions 211 thereon is extending near top surface of the N epitaxial layer 202 and surrounding the gate electrode 207 padded by the second insulating film 209. The P body regions 210, the n+ source regions 211 and the shielded gate electrodes 205 are further shorted to a source metal 212 through a plurality of trenched contacts 213 filled with contact plugs and surrounded by p+ heavily doped regions 214 around bottoms underneath the n+ source regions 211. According to the invention, an oxide charge balance region is therefore formed between upper portion of adjacent gate trenches 203. Meanwhile, P regions 215 are introduced into the N epitaxial layer 202 to form a super junction to act as junction charge balance region, comprising a plurality of alternating P regions 215 and N regions 202 above the N+ substrate 201 and below the oxide charge balance region to ensure that whole drift region is fully depleted and breakdown occurs at middle of adjacent trenched gates without having early breakdown voltage occurring at trench bottom, and at the same time, to significantly relax the sensitivity of breakdown voltage on trench bottom thickness and trench depth. According to this embodiment, the super junction region is surrounding with at least lower portion of the trenched gates, wherein lower portion of the shielded gates 205 in the second type gate trenches 204 is surrounded by the super junction region, and the P regions 215 is above the bottom surface 216 of the N epitaxial layer 202. The P regions 215 can be easily formed along sidewalls and bottoms of the second type gate trenches 204 by an angle ion-implantation of boron through sidewalls and bottoms of the second type gate trenches 204.

Please refer to FIG. 2B for another preferred embodiment of the present invention, compared with FIG. 2A, the N-channel trenched semiconductor power device in FIG. 2B is formed in an epitaxial layer, which further comprises a lower N1 epitaxial layer 302-1 between the N+ substrate 301 and the super junction region with resistivity R1 and an upper N2 epitaxial layer 302-2 with resistivity R2, wherein R1<R2. Moreover, the super junction region comprises a plurality of alternating P regions 315 and N2 regions 302-2 above the N1 epitaxial layer 302-1, wherein the P regions 315 touch to bottom surface 316 of the upper N2 epitaxial layer 302-2.

Please refer to FIG. 2C for another preferred embodiment of the present invention, compared with FIG. 2B, the N-channel trenched semiconductor power device in FIG. 2C is formed in an epitaxial layer, which further comprises a lower N1 epitaxial layer 402-1 between the N+ substrate 401 and the super junction region with resistivity R1, a middle N2 epitaxial layer 402-2 located in the super junction region with resistivity R2 and an upper N3 epitaxial layer 402-3 with resistivity R3, wherein R1<R2<R3 or R1<R3<R2.

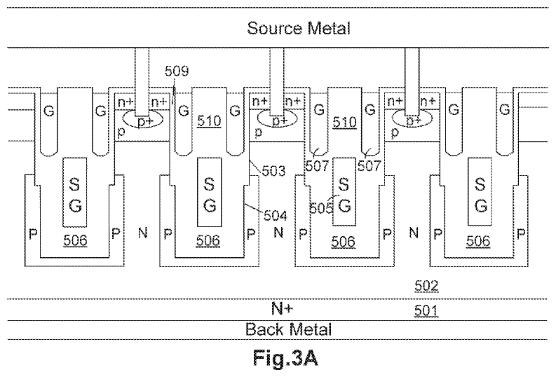

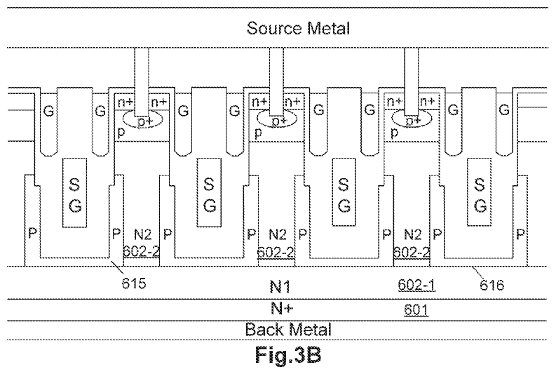

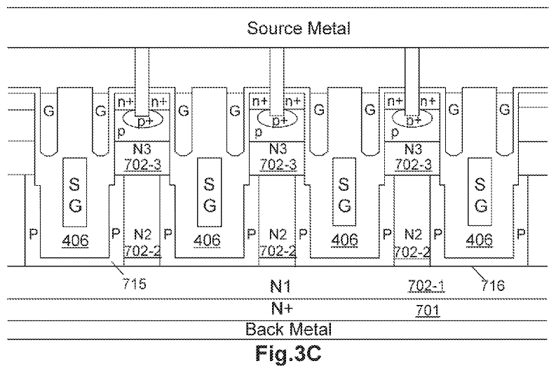

Please refer to FIG. 3A for another preferred embodiment of the present invention, the N-channel trenched semiconductor power device has a similar structure to FIG. 2A, except that, a shielded gate electrode 505 (SG, as illustrated) is disposed in the middle of the second type gate trenches 504 and lower portion of the first type gate trenches 503, and a pair of split gate electrodes 507 are separated from each other by a third insulating film 510, which is formed by fully oxidizing upper portion of the shielded gate electrode 505 during a gate oxide layer 509 thermally grown.

Please refer to FIG. 3B for another preferred embodiment of the present invention, compared with FIG. 3A, the N-channel trenched semiconductor power device in FIG. 3B is formed in an epitaxial layer, which further comprises a lower N1 epitaxial layer 602-1 between the N+ substrate 601 and the super junction region with resistivity R1 and an upper N2 epitaxial layer 602-2 with resistivity R2, wherein R1<R2. Moreover, the super junction region comprises a plurality of alternating P regions 615 and N2 regions 602-2 above the N1 epitaxial layer 602-1, wherein the P regions 615 touch to bottom surface 616 of the upper N2 epitaxial layer 602-2.

Please refer to FIG. 3C for another preferred embodiment of the present invention, compared with FIG. 3B, the N-channel trenched semiconductor power device in FIG. 3C is formed in an epitaxial layer, which further comprises a lower N1 epitaxial layer 702-1 between the N+ substrate 701 and bottom of trenched gates with resistivity R1, a middle N2 epitaxial layer 702-2 located in the super junction region with resistivity R2 and an upper N3 epitaxial layer 702-3 with resistivity R3, wherein R1<R2<R3 or R1<R3<R2.

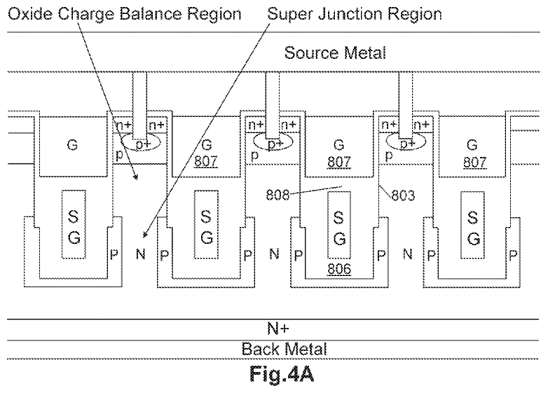

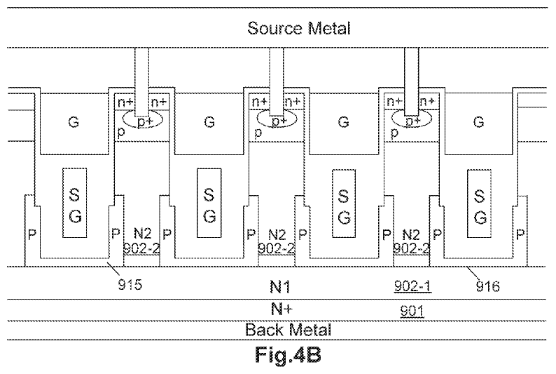

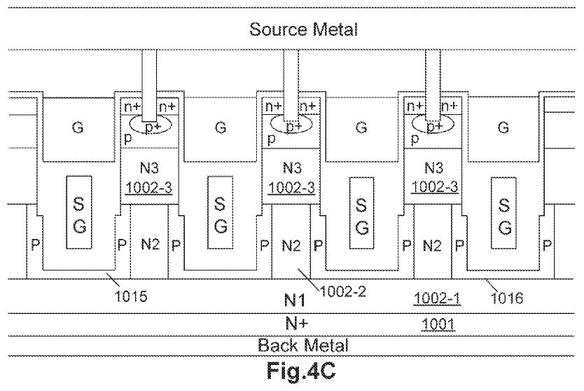

Please refer to FIG. 4A for another preferred embodiment of the present invention, the N-channel trenched semiconductor power device has a similar structure to FIG. 3A, except that, inside each of the trenched gates 803, the gate electrode is a single gate electrode 807, which is disposed in upper portion of the gate trenches, and is isolated from the shielded gate electrode 805 by a fourth insulating film 808.

Please refer to FIG. 4B for another preferred embodiment of the present invention, compared with FIG. 4A, the N-channel trenched semiconductor power device in FIG. 4B is formed in an epitaxial layer, which further comprises a lower N1 epitaxial layer 902-1 between the N+ substrate 901 and the super junction region with resistivity R1 and an upper N2 epitaxial layer 902-2 with resistivity R2, wherein R1<R2. Moreover, the super junction region comprises a plurality of alternating P regions 915 and N2 regions 902-2 above the N1 epitaxial layer 902-1, wherein the P regions 915 touch to bottom surface 916 of the upper N2 epitaxial layer 902-2.

Please refer to FIG. 4C for another preferred embodiment of the present invention, compared with FIG. 4B, the N-channel trenched semiconductor power device in FIG. 4C is formed in an epitaxial layer, which further comprises a lower N1 epitaxial layer 1002-1 between the N+ substrate 1001 and the super junction region with resistivity R1, a middle N2 epitaxial layer 1002-2 located in the super junction region with resistivity R2 and an upper N3 epitaxial layer 1002-3 with resistivity R3, wherein R1<R2<R3 or R1<R3<R2.

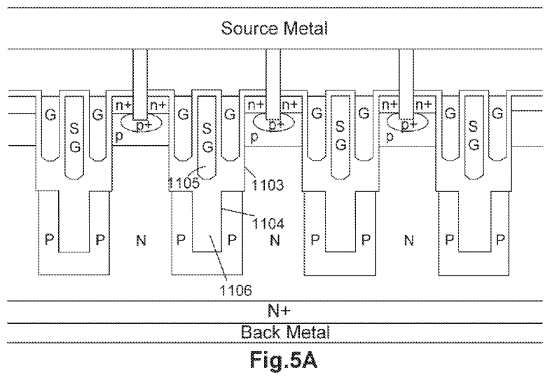

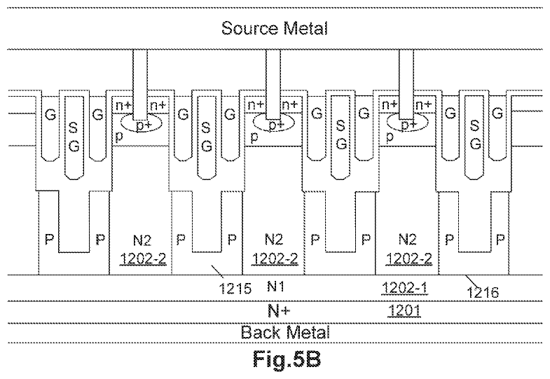

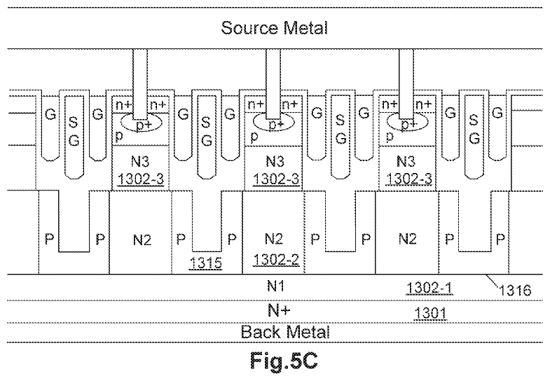

Please refer to FIG. 5A for another preferred embodiment of the present invention, the N-channel trenched semiconductor power device has a similar structure to FIG. 2A, except that, the second type gate trenches 1104 is narrower than that in FIG. 2A, and is fully filled up by the first insulation film 1106, and the shielded gate electrode 1105 is disposed in the middle of the first type gate trenches 1103.

Please refer to FIG. 5B for another preferred embodiment of the present invention, compared with FIG. 5A, the N-channel trenched semiconductor power device in FIG. 5B is formed in an epitaxial layer, which further comprises a lower N1 epitaxial layer 1202-1 between the N+ substrate 1201 and the super junction region with resistivity R1 and an upper N2 epitaxial layer 1202-2 with resistivity R2, wherein R1<R2. Moreover, the super junction region comprises a plurality of alternating P regions 1215 and N2 regions 1202-2 above the N1 epitaxial layer 1202-1, wherein the P regions 915 touch to bottom surface 916 of the upper N2 epitaxial layer 1202-2.

Please refer to FIG. 5C for another preferred embodiment of the present invention, compared with FIG. 5B, the N-channel trenched semiconductor power device in FIG. 5C is formed in an epitaxial layer, which further comprises a lower N1 epitaxial layer 1302-1 between the N+ substrate 1301 and the super junction region with resistivity R1, a middle N2 epitaxial layer 1302-2 located in the super junction region with resistivity R2 and an upper N3 epitaxial layer 1302-3 with resistivity R3, wherein R1<R2<R3 or R1<R3<R2.

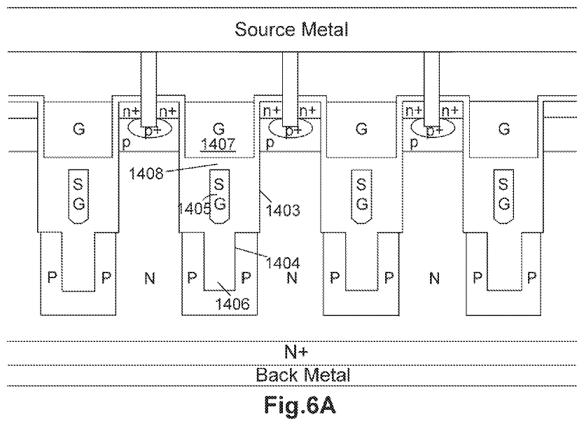

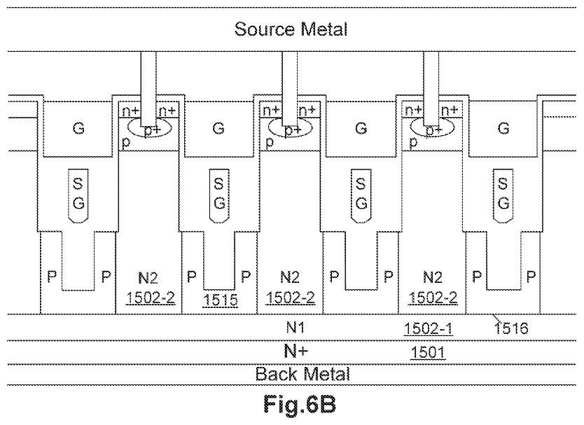

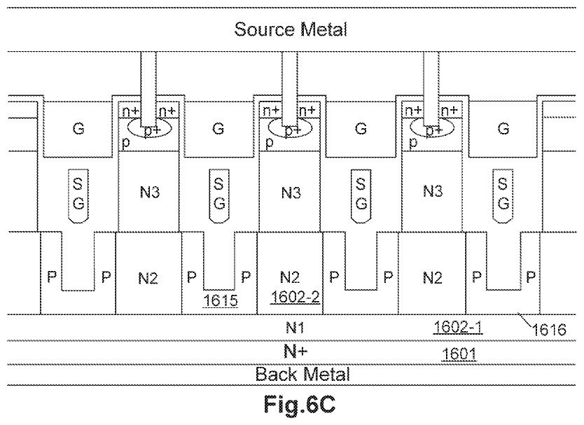

Please refer to FIG. 6A for another preferred embodiment of the present invention, the N-channel trenched semiconductor power device has a similar structure to FIG. 5A, except that, inside each of the first type gate trenches 1403, the single gate electrode 1407 is disposed along upper portion of the trenches, the shielded gate electrode 1405 (SC as illustrated) is disposed in the middle and lower portion of the first type gate trenched 1403, while the second type gate trenches 1404 is fully filled with the first insulating film 1406, and the gate electrode 1407 is isolated from the shielded gate electrode 1405 by a fourth insulating film 1408.

Please refer to FIG. 6B for another preferred embodiment of the present invention, compared with FIG. 6A, the N-channel trenched semiconductor power device in FIG. 5B is formed in an epitaxial layer, which further comprises a lower N1 epitaxial layer 1502-1 between the N+ substrate 1501 and the super junction region with resistivity R1 and an upper N2 epitaxial layer 1502-2 with resistivity R2, wherein R1<R2. Moreover, the super junction region comprises a plurality of alternating P regions 1515 and N2 regions 1502-2 above the N1 epitaxial layer 1502-1, wherein the P regions 1515 touch to bottom surface 1516 of the upper N2 epitaxial layer 1502-2.

Please refer to FIG. 6C for another preferred embodiment of the present invention, compared with FIG. 6B, the N-channel trenched semiconductor power device in FIG. 6C is formed in an epitaxial layer, which further comprises a lower N1 epitaxial layer 1602-1 between the N+ substrate 1601 and the super junction with resistivity R1, a middle N2 epitaxial layer 1602-2 located in the super junction region with resistivity R2 and an upper N3 epitaxial layer 1602-3 with resistivity R3, wherein R1<R2<R3 or R1<R3<R2.

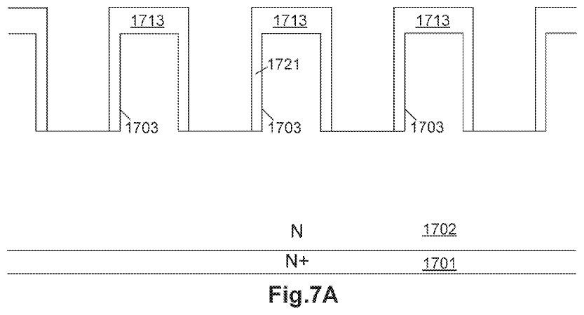

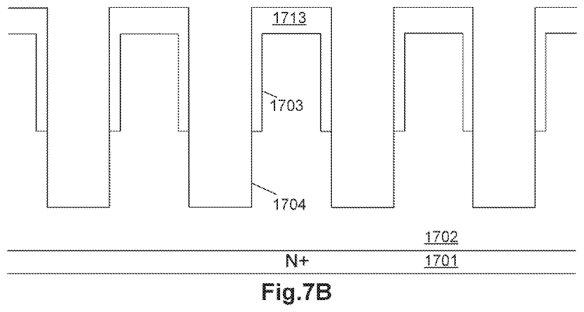

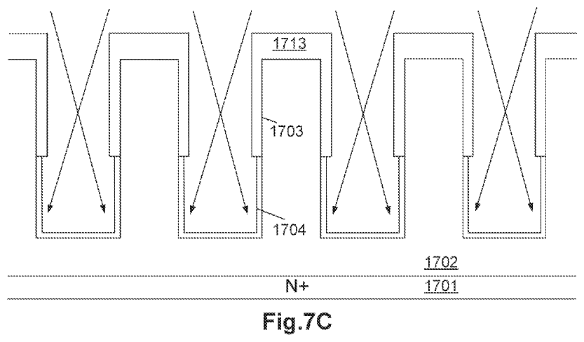

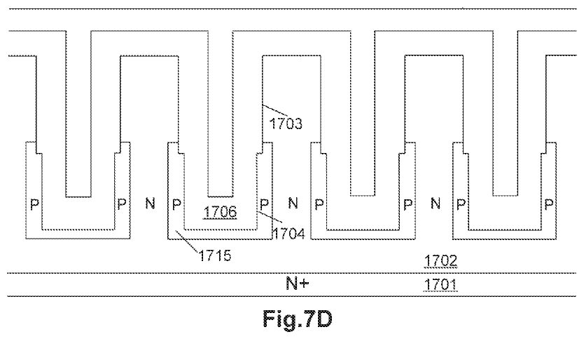

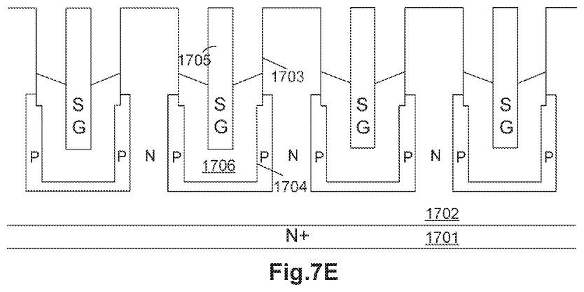

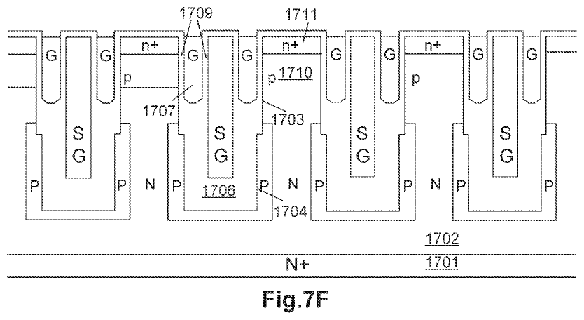

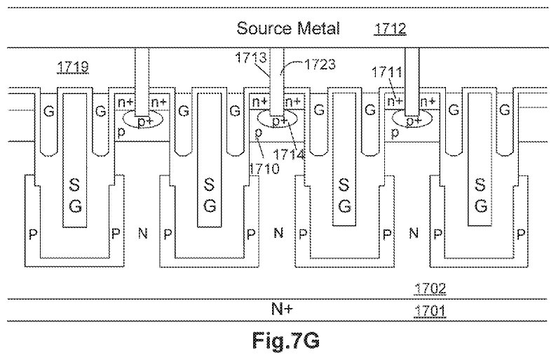

FIGS. 7A-7G are a serial of exemplary steps that are performed to form the invention embodiment of FIG. 2A, wherein the wide second type gate trench is filled up with both first insulating film and shielded gate electrode. In FIG. 7A, an N epitaxial layer 1702 is grown on an N+ substrate 1701, wherein the N epitaxial layer 1702 has a lower doping concentration than the N+ substrate 1701. A hard mask 1713 such as an oxide layer is formed onto a top surface of the N epitaxial layer 1702 for definition of areas for a plurality of first type gate trenches. Then, after dry oxide etch and dry silicon etch, a plurality of first type gate trenches 1703 are formed penetrating through open regions in the hard mask, the N epitaxial layer 1702, and not reaching the bottom surface of N epitaxial layer 1702. Mesas are formed between every two adjacent gate trenches in the N epitaxial layer 1702. Then, a sacrificial oxide layer (not shown) is first grown and then removed to eliminate the plasma damage after forming the gate trenches 1703. Then, a dielectric layer 1721 is formed by oxide deposition or thermal oxide growing method on sidewalls and bottoms of the first type gate trenches 1703. Oxide layer on bottoms of the first type gate trenches 1703 is then removed by dry oxide etching.

In FIG. 7B, an anisotropic silicon etch is performed to form a plurality of the second type gate trenches 1704.

In FIG. 7C, an angle boron ion implantation into lower portion sidewalls and bottom of the second type gate trenches 1704 and a diffusion step are successively carried out to form a P region.

In FIG. 7D, the hard mask 1713 and the dielectric layer 1721 on the sidewalls of the first type gate trench are removed, then, a first gate insulating film 1706 comprising a thick oxide layer is formed along inner surfaces of the first and second gate trenches 1703 and 1704 and top surface of epitaxy layer 1702 by thermal oxide growth or thick oxide deposition. Then, a first doped poly-silicon layer is deposited onto the first gate insulating film 1706 to fill the first type gate trenches 1703 and second type gate trenches 1704.

In FIG. 7E, the first doped poly-silicon layer is etched back by CMP (Chemical Mechanical Polishing) or Plasma Etch or Poly recess etch to serve as the shielded gate electrodes 1705 (SG, as illustrated), wherein the shielded gate electrodes 1705 is disposed in both the first type gate trenches 1703 and second type gate trenches 1704. Next, the first gate insulating film 1706 is etched back from top surface of the epitaxial layer and an upper portion of the gate trenches 1703.

In FIG. 7F, a second gate insulating film 1709 comprising a thin oxide layer is grown along upper inner surfaces of the first type gate trenches 1703, covering a top surface of the first insulating film 1706 and the shielded gate electrode 1705. After that, a second doped poly-silicon layer is deposited filling the upper portion of the gate trenches 1703, and is then etched back by CMP (Chemical Mechanical Polishing) or Plasma Etch to serve as split gate electrodes 1707. Each of the split gate electrodes 1707 is symmetrically disposed in the middle between the shielded gate electrode 1705 and adjacent to trench sidewall in the first type gate trenches 1703. Then, a body implantation of p conductivity type dopant is carried out over entire top surface to form p body regions 1710 between every two adjacent gate trenches 1703. After applying a source mask (not shown) onto the top surface of the epitaxial layer, a source implantation of n conductivity type dopant and a diffusion step are successively carried out to form an n+ source region 1711 near a top surface of the p body regions 1710 between two adjacent gate trenches 1703.

In FIG. 7G, another oxide layer is deposited onto the top surface of the epitaxial layer 1702 to serve as a contact interlayer 1719. Then, after applying a contact mask (not shown) onto the contact interlayer 1719, a plurality of trenched contacts 1713 are formed by successively dry oxide etch and dry silicon etch penetrating through the contact interlayer 1719, and extending into the p body regions 1710 for trenched source-body contacts. Next, a BF2 Ion Implantation is performed to form a p+ body contact doped region 1714 within the p body regions 1710 and surrounding at least bottom of the trenched source body-contacts penetrating through the n+ source region 1711 and extending into the p body region 1710. Then, a barrier metal layer of Ti/TiN or Co/TiN or Ta/TiN is deposited on sidewalls and bottoms of all the trenched contacts 1713 followed by a step of RTA process for silicide formation. Then, a tungsten material layer is deposited onto the barrier layer, wherein the tungsten material layer and the barrier layer are then etched back to form contact metal plug 1723 for the trenched source-body contacts. Then, a metal layer of Al alloys or Cu padded by a resistance-reduction layer Ti or Ti/TiN underneath is deposited onto the contact interlayer 1719 and followed by a metal etching process by employing a metal mask (not shown) to be patterned as a source metal 1712.

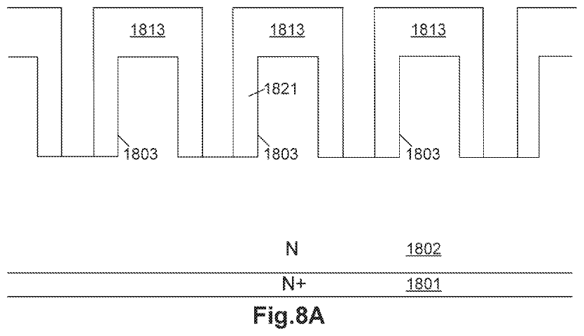

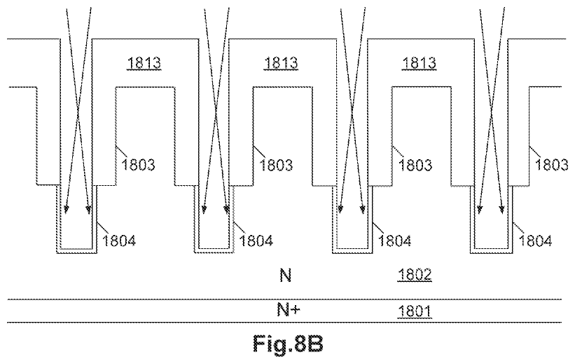

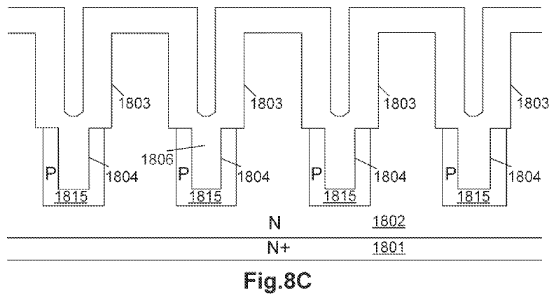

FIGS. 8A-8C are a serial of exemplary steps that are performed to form the invention embodiments of FIGS. 5A-5C and 6A-6C wherein the narrow second gate trench is fully filled up with oxide. In FIG. 8A, an N epitaxial layer 1802 is grown on an N+ substrate 1801, wherein the N epitaxial layer 1802 has a lower doping concentration than the N+ substrate 1801. A hard mask 1813 such as an oxide layer is formed onto a top surface of the N epitaxial layer 1802 for definition of areas for a plurality of first type gate trenches. Then, after dry oxide etch and dry silicon etch, a plurality of first type gate trenches 1803 are formed penetrating through open regions in the hard mask, the N epitaxial layer 1802, and not reaching the bottom surface of N epitaxial layer 1802. Mesas are formed between every two adjacent gate trenches in the N epitaxial layer 1802. Then, a sacrificial oxide layer (not shown) is first grown and then removed to eliminate the plasma damage after forming the gate trenches 1803. Then, a dielectric layer 1821 is formed by oxide deposition or thermal oxide growing method on sidewalls and bottoms of the first type gate trenches 1803. Oxide layer on bottoms of the first type gate trenches 1803 is then removed by dry oxide etching.

In FIG. 8B, an anisotropic silicon etch is performed to form a plurality of the second type gate trenches 1804. An angle boron ion implantation into lower portion sidewalls and bottom of the second type gate trenches 1804 and a diffusion step are successively carried out to form a P region.

In FIG. 8C, the hard mask 1813 and the dielectric layer 1821 are removed, then, a first gate insulating film 1806 comprising a thick oxide layer is formed along inner surfaces of the first type gate trenches 1803 and the second type gate trenches 1804 and top surface of epitaxy layer 1802 by thermal oxide growth or thick oxide deposition, wherein the second type gate trenches is narrow enough to be fully filled up by the first insulation film 1806. Then, a first doped poly-silicon layer is deposited onto the first gate insulating film 1806 filling the first type gate trenches 1803 to serve as a shielded electrode.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trenched semiconductor power device comprising an SGT MOSFET formed in an epitaxial layer of a first conductivity type onto a substrate of said first conductivity type, further comprising:
a plurality of trenched gates surrounded by source regions of said first conductivity type encompassed in body regions of a second conductivity type near a top surface of said epitaxial layer, each of said trenched gates including a gate electrode and a shielded gate electrode;
an oxide charge balance region formed between upper portion of adjacent said trenched gates;
a super junction region surrounding with lower portion of said trenched gates, comprising a first doped column region of said second conductivity type formed adjacent to sidewalls of said trenched gates and a second doped column region of said first conductivity type formed in parallel and surrounded with said first doped column regions below said body region;
said shielded gate electrode being insulated from said epitaxial layer by a first insulating film and said gate electrode being insulated from said epitaxial layer by a second insulating film having a less thickness than said first insulating film, said shielded gate electrode and said gate electrode being insulated from each other; and
said body regions, said shielded gate electrodes and said source regions being shorted to a source metal through a plurality of trenched contacts.

2. The trenched semiconductor power device of claim 1, wherein each of said trenched gates has a first type gate trench and a second type gate trench; said second type gate trench is below said first type gate trench and has trench width narrower than said first type gate trench, and said super junction region surrounds with said second type gate trench.

3. The trenched semiconductor power device of claim 1, wherein said epitaxial layer comprises a single epitaxial layer having uniform doping concentration.

4. The trenched semiconductor power device of claim 1, wherein said epitaxial layer comprises a lower epitaxial layer between said substrate and said super junction region with resistivity R1 and an upper epitaxial layer with resistivity R2, wherein R1<R2.

5. The trenched semiconductor power device of claim 1, wherein said epitaxial layer comprises a lower epitaxial layer between said substrate and said super junction region with resistivity R1, a middle epitaxial layer located in said super junction region with resistivity R2 and an upper epitaxial layer with resistivity R3, wherein R1<R2<R3 or R1<R3<R2.

6. The trenched semiconductor power device of claim 1, wherein said super junction region surrounding with at least lower portion of shielded gate electrode.

7. The trenched semiconductor power device of claim 1, wherein lower portion of said trenched gates has a narrow trench fully filled up with said first insulating film and is surrounded by said super junction region.

8. The trenched semiconductor power device of claim 1, wherein said shielded gate electrode is disposed in the middle and said gate electrode is a pair of split gate electrodes disposed surrounding upper portion of said shielded gate electrode, said gate electrode and said shielded gate electrode are insulated from each other by said second insulating film grown on upper portion of said shielded gate electrode.

9. The trenched semiconductor power device of claim 8, wherein said upper portion of said shielded gate electrode surrounded by said gate electrode is fully oxidized as during said second insulating film grown when said shielded gate electrode is thin enough.

10. The trenched semiconductor power device of claim 1, wherein said shielded gate electrode is disposed in lower portion of each said trenched gate, and is isolated from said epitaxial layer by said first insulating film, said gate electrode is disposed in upper portion of each said trenched gate, and is isolated from said shielded gate electrode by a third insulating film.

11. A method for manufacturing a trench semiconductor power device comprising the steps of:
growing an epitaxial layer of a first conductivity type onto a substrate of the first conductivity type, wherein the epitaxial layer having a lower doping concentration than the substrate;
forming a trench mask onto a top surface of said epitaxial layer for definition of a plurality of first type gate trenches;
forming said first type gate trenches, and a mesa between two adjacent gate trenches in said epitaxial layer by etching through open regions in the trench mask;
forming a dielectric layer on sidewalls and bottoms of said first type gate trenches;
removing said bottoms of said first type gate trenches by anisotropic etch;
performing an anisotropic silicon etch to form a plurality of second type gate trenches; and
carrying out an angle Ion Implantation of said second conductivity type dopant into said sidewalls and bottoms of said second type gate trenches.

12. The method of claim 11, further comprising the steps of:
forming a first insulating film along inner surfaces of said first type and said second type gate trenches; and
depositing a first doped poly-silicon layer filling said first type and second type gate trenches to serve as a shielded gate electrode in said first type and second type gate trenches;
etching back said first insulation layer of upper portion of said first gate trench sidewalls for formation of a pair of gate electrodes surrounding said shielded gate electrode;
forming a gate oxide layer along upper sidewalls of said first type gate trenches; and
depositing a second doped poly-silicon layer to serve as said pair of gate electrodes.

13. The method of claim 11, further comprising the steps of:
forming a first insulating film along inner surfaces of said first type and said second type gate trenches, wherein said second type gate trenches is fully filled up by said first insulation film;
depositing a first doped poly-silicon layer filling said first type gate trenches to serve as a shielded gate electrode in said first type gate trenches;
etching back said first insulating layer of upper sidewalls of said first type gate trenches for formation of a pair of gate electrodes surrounding said shielded gate electrode;
forming a gate oxide layer along upper sidewalls of said first type gate trenches; and
depositing a second doped poly-silicon layer to serve as said pair of gate electrodes.

14. The method of claim 11, further comprising the steps of:
forming a first insulating film along inner surfaces of said first type and said second type gate trenches; and
depositing a first doped poly-silicon layer filling said first type and second type gate trenches to serve as a shielded gate electrode;
etching back said first doped poly-silicon to form a shielded gate electrode in said second type gate trenches and lower portion of said first type gate trenches;
etching back said first insulating layer of upper portion of said first gate trench sidewalls for formation of a gate electrode in upper portion of said first type gate trench;
forming a gate oxide layer along upper sidewalls of said first type gate trenches; and
depositing a second doped poly-silicon layer to serve as said gate electrode.

15. The method of claim 11, further comprising the steps of:
forming a first insulation film along inner surfaces of said first type and said second type gate trenches, wherein said second type gate trench is fully filled up by said first insulation film;
depositing a first doped poly-silicon layer filling said first type gate trenches to serve as a shielded gate electrode;
etching back said first doped poly-silicon to form said shielded gate electrode in lower portion of said first type gate trenches;
etching back said first insulating layer of upper portion of said first gate trench sidewalls for formation of a gate electrode in upper portion of said first type gate trenches;
forming a gate oxide layer along upper sidewalls of said first type gate trenches; and
depositing a second doped poly-silicon layer to serve as said gate electrode.
